(19) United States
(12) Patent Application Publication
(10) Pub. No.: US 2025/0386544 A1
(43) Pub. Date: Dec. 18, 2025

(54) PLACEHOLDER STRUCTURE WITH DIELECTRIC LINER

(71) Applicant: International Business Machines Corporation, Armonk, NY (US)

(72) Inventors: Fabio Carta, Pleasantville, NY (US); Tao Li, Slingerlands, NY (US); Ruilong Xie, Niskayuna, NY (US); Shogo Mochizuki, Mechanicville, NY (US)

(21) Appl. No.: 18/746,538

(22) Filed: Jun. 18, 2024

(51) Int. Cl. H01L 29/417; H01L 21/768; H01L 21/8234; H01L 23/528; H01L 27/088; H01L 29/06; H01L 29/08; H01L 29/423; H01L 29/66; H01L 29/775; H01L 29/786

(52) U.S. Cl. CPC H10D 30/6729; H01L 21/76816; H01L 21/76831; H01L 23/5283; H01L 23/5286; H10D 62/151; H10D 84/013; H10D 84/0149; H10D 84/038; H10D 84/83; H10D 30/014; H10D 30/43; H10D 30/6735; H10D 30/6757; H10D 62/121

(57) ABSTRACT

A semiconductor device includes a first source/drain contact disposed beneath a first source/drain region and a placeholder disposed beneath a second source/drain region. The placeholder includes a first portion including a first material having a first concentration of germanium and a second portion including a second material having a second concentration of germanium that is different than the first concentration.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

### SUMMARY

Embodiments of the invention provide techniques for forming a placeholder structure with dielectric liner for backside power delivery network (BSPDN).

In one embodiment, a semiconductor device includes a first source/drain contact disposed beneath a first source/drain region and a placeholder disposed beneath a second source/drain region. The placeholder includes a first portion including a first material having a first concentration of germanium and a second portion including a second material having a second concentration of germanium that is different than the first concentration.

In another embodiment, a semiconductor device includes a semiconductor device including a first and a second source/drain region, a backside contact disposed beneath the first source/drain region, and a placeholder disposed beneath the second source/drain region. The placeholder includes a high germanium content portion and a low germanium content portion, where the high germanium content portion is adjacent to the second source/drain region.

In yet another embodiment, a method includes performing a first etch process to create a trench in a semiconductor substrate, forming a protective liner on vertical sidewalls of the trench, and performing a second etch process to deepen the trench to below the protective liner and to laterally enlarge the portion of the trench that is below the protective liner. The method includes forming a first portion of a placeholder in the trench, where the first portion includes a first material having a first concentration of germanium. The method also includes forming a second portion of the placeholder adjacent to the first portion, where the second portion includes a second material having a second concentration of germanium that is different than the first concentration.

These and other features and advantages of embodiments described herein will become more apparent from the accompanying drawings and the following detailed description.

### BRIEF DESCRIPTION OF THE DRAWINGS

FIG. 1 depicts a top view of a semiconductor structure indicating X, Y1, and Y2 cross-section locations on which the cross-sectional views of FIGS. 2A-15C are based.

FIG. 2A depicts a first cross-sectional view corresponding to line X in FIG. 1 illustrating the semiconductor structure of FIG. 1 during an intermediate step of a method of fabricating a nanosheet transistor structure, according to an illustrative embodiment.

FIG. 2B depicts a second cross-sectional view corresponding to line Y1 in FIG. 1 illustrating the semiconductor structure of FIG. 1 during the intermediate step of a method of fabricating a nanosheet transistor structure, according to an illustrative embodiment.

FIG. 2C depicts a second cross-sectional view corresponding to line Y2 in FIG. 1 illustrating the semiconductor structure of FIG. 1 during the intermediate step of a method of fabricating a nanosheet transistor structure, according to an illustrative embodiment.

FIG. 3A depicts a first cross-sectional view corresponding to the line X in FIG. 1 following removal of exposed portions of a bottom dielectric insulator (BDI) layer and formation of a shallow cavity, according to an illustrative embodiment.

FIG. 3B depicts a second cross-sectional view corresponding to the line Y1 in FIG. 1 following removal of the exposed portions of the BDI layer and formation of the shallow cavity, according to an illustrative embodiment.

FIG. 3C depicts a third cross-sectional view corresponding to the line Y2 in FIG. 1 following removal of the exposed portions of the BDI layer and formation of the shallow cavity, according to an illustrative embodiment.

FIG. 4A depicts a first cross-sectional view corresponding to the line X in FIG. 1 following formation of a sidewall liner, according to an illustrative embodiment.

FIG. 4B depicts a second cross-sectional view corresponding to the line Y1 in FIG. 1 following formation of the sidewall liner, according to an illustrative embodiment.

FIG. 4C depicts a third cross-sectional view corresponding to the line Y2 in FIG. 1 following formation of the sidewall liner, according to an illustrative embodiment.

FIG. 5A depicts a first cross-sectional view corresponding to the line X in FIG. 1 following formation of a placeholder cavity with lateral enlargement, according to an illustrative embodiment.

FIG. 5B depicts a second cross-sectional view corresponding to the line Y1 in FIG. 1 following formation of the placeholder cavity with lateral enlargement, according to an illustrative embodiment.

FIG. 5C depicts a third cross-sectional view corresponding to the line Y2 in FIG. 1 following formation of the placeholder cavity with lateral enlargement, according to an illustrative embodiment.

FIG. 6A depicts a first cross-sectional view corresponding to the line X in FIG. 1 following formation of a first placeholder layer, according to an illustrative embodiment.

FIG. 6B depicts a second cross-sectional view corresponding to the line Y1 in FIG. 1 following the formation of the first placeholder layer, according to an illustrative embodiment.

FIG. 6C depicts a third cross-sectional view corresponding to the line Y2 in FIG. 1 following the partial formation of the first placeholder layer, according to an illustrative embodiment.

FIG. 7A depicts a first cross-sectional view corresponding to the line X in FIG. 1 following formation of a second placeholder layer, according to an illustrative embodiment.

FIG. 7B depicts a second cross-sectional view corresponding to the line Y1 in FIG. 1 following the formation of the second placeholder layer, according to an illustrative embodiment.

FIG. 7C depicts a third cross-sectional view corresponding to the line Y2 in FIG. 1 following the formation of the second placeholder layer, according to an illustrative embodiment.

FIG. 8A depicts a first cross-sectional view corresponding to the line X in FIG. 1 following epitaxial source/drain region formation, according to an illustrative embodiment.

FIG. 8B depicts a second cross-sectional view corresponding to the line Y1 in FIG. 1 following the epitaxial source/drain region formation, according to an illustrative embodiment.

FIG. 8C depicts a third cross-sectional view corresponding to the line Y2 in FIG. 1 following the epitaxial source/drain region formation, according to an illustrative embodiment.

FIG. 9A depicts a first cross-sectional view corresponding to the line X in FIG. 1 following chemical mechanical planarization (CMP), replacement metal gate (RMG) formation, middle-of-line (MOL) contact formation, back-end-of-line (BEOL) interconnect formation, and carrier wafer bonding, according to an illustrative embodiment.

FIG. 9B depicts a second cross-sectional view corresponding to the line Y1 in FIG. 1 following the CMP, the RMG formation, the MOL contact formation, the BEOL interconnect formation, and the carrier wafer bonding, according to an illustrative embodiment.

FIG. 9C depicts a third cross-sectional view corresponding to the line Y2 in FIG. 1 following the CMP, the RMG formation, the MOL contact formation, the BEOL interconnect formation, and the carrier wafer bonding, according to an illustrative embodiment.

FIG. 10A depicts a first cross-sectional view corresponding to the line X in FIG. 1 following wafer flipping and removal of a semiconductor substrate layer up to an etch stop layer, according to an illustrative embodiment.

FIG. 10B depicts a second cross-sectional view corresponding to the line Y1 in FIG. 1 following wafer flipping and removal of the semiconductor substrate layer up to the etch stop layer, according to an illustrative embodiment.

FIG. 10C depicts a third cross-sectional view corresponding to the line Y2 in FIG. 1 following wafer flipping and removal of the semiconductor substrate layer up to the etch stop layer, according to an illustrative embodiment.

FIG. 11A depicts a first cross-sectional view corresponding to the line X in FIG. 1 following etch stop layer removal and removal of the remaining semiconductor substrate layer, according to an illustrative embodiment.

FIG. 11B depicts a second cross-sectional view corresponding to the line Y1 in FIG. 1 following the etch stop layer removal and removal of the remaining semiconductor substrate layer, according to an illustrative embodiment.

FIG. 11C depicts a third cross-sectional view corresponding to the line Y2 in FIG. 1 following the etch stop layer removal and removal of the remaining semiconductor substrate layer, according to an illustrative embodiment.

FIG. 12A depicts a first cross-sectional view corresponding to the line X in FIG. 1 following backside inter-layer dielectric (ILD) layer formation and backside contact patterning, according to an illustrative embodiment.

FIG. 12B depicts a second cross-sectional view corresponding to the line Y1 in FIG. 1 following the backside ILD layer formation and the backside contact patterning, according to an illustrative embodiment.

FIG. 12C depicts a third cross-sectional view corresponding to the line Y2 in FIG. 1 following the backside ILD layer formation and the backside contact patterning, according to an illustrative embodiment.

FIG. 13A depicts a first cross-sectional view corresponding to the line X in FIG. 1 following selective removal of the first placeholder layer, according to an illustrative embodiment.

FIG. 13B depicts a second cross-sectional view corresponding to the line Y1 in FIG. 1 following the selective removal of the first placeholder layer, according to an illustrative embodiment.

FIG. 13C depicts a third cross-sectional view corresponding to the line Y2 in FIG. 1 following the selective removal of the first placeholder layer, according to an illustrative embodiment.

FIG. 14A depicts a first cross-sectional view corresponding to the line X in FIG. 1 following a directional etch, according to an illustrative embodiment.

FIG. 14B depicts a second cross-sectional view corresponding to the line Y1 in FIG. 1 following the directional etch, according to an illustrative embodiment.

FIG. 14C depicts a third cross-sectional view corresponding to the line Y2 in FIG. 1 following the directional etch, according to an illustrative embodiment.

FIG. 15A depicts a first cross-sectional view corresponding to the line X in FIG. 1 following backside contact and backside interconnect formation, according to an illustrative embodiment.

FIG. 15B depicts a second cross-sectional view corresponding to the line Y1 in FIG. 1 following the backside contact and the backside interconnect formation, according to an illustrative embodiment.

FIG. 15C depicts a third cross-sectional view corresponding to the line Y2 in FIG. 1 following the backside contact and the backside interconnect formation, according to an illustrative embodiment.

### DETAILED DESCRIPTION

Illustrative embodiments of the invention may be described herein in the context of illustrative methods for forming placeholder structures for backside power delivery, along with illustrative apparatus, systems, and devices formed using such methods. However, it is to be understood that embodiments of the invention are not limited to the illustrative methods, apparatus, systems, and devices but instead are more broadly applicable to other suitable methods, apparatus, systems, and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

A FET is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the size of FETs. One technique is through the use of fin-shaped channels in fin field-effect transistors (FinFET). Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures, the gate can more effectively control the channel, as the gate extends over more than one side or surface of the channel. In some FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 1 to 20 nanometers (nm). Nanosheets and nanowires are viable options for scaling to 7 nm and beyond. A general process flow for forming a nanosheet stack involves selectively removing sacrificial layers, which may be formed of silicon germanium (SiGe), between sheets of channel material, which may be formed of silicon (Si).

For continued scaling (e.g., to 2.5 nm and beyond), next-generation stacked FET devices may be used. Next-generation stacked FET devices provide a complex gate-all-around (GAA) structure. Conventional GAA FETs, such as nanosheet FETs, may stack multiple p-type nanowires or nanosheets on top of each other in one device, and may stack multiple n-type nanowires or nanosheets on top of each other in another device. Next-generation stacked FET structures provide improved track height scaling, leading to structural gains (e.g., such as 30-40% structural gains for different types of devices, such as logic devices, static random-access memory (SRAM) devices, etc.). In next-generation stacked FET structures, n-type and p-type nanowires or nanosheets are stacked on each other, eliminating n-to-p separation bottlenecks and reducing the device area footprint. There is, however, a continued desire for further scaling and reducing the size of FETs.

As discussed above, various techniques may be used to reduce the size of FETs, including using fin-shaped channels in FinFET devices, using stacked nanosheet channels formed over a semiconductor substrate, and using next-generation stacked FET devices.

Although embodiments described herein are discussed in connection with nanosheet stacks, the embodiments are not necessarily limited thereto, and may similarly apply to nanowire stacks.

The concept of buried power rail (BPR) refers to power rails that are buried below the BEOL metal stack, usually in-level with the transistor fins themselves. BSPDN, or grids, enable scaling beyond 5 nm with the backside being below the transistor substrate. The BPR technology enables the freeing up of resources for the dense logic connections often limiting modern processor performance. Further scaling of a standard logic cell is enabled by removing the overhead in the area occupied by the power rails. Finally, thicker low-resistance power rails are allowed, which enable lower voltage (IR) drops.

Conventional techniques typically utilize a uniform semiconductor material, such as SiGe with a consistent germanium concentration, for contact placeholder formation. After placeholder, source/drain, and frontside BEOL interconnect formation, the carrier wafer is flipped. The silicon substrate then needs to be selectively removed without damaging the placeholder. If the placeholder is damaged it can be difficult or impossible to form a contact. Using a higher germanium concentration for the placeholder material can provide improved selectivity for substrate removal, but it is also more susceptible to damage during front-end-of-line (FEOL) fabrication of source/drain regions due to its sensitivity to cleaning processes.

Some embodiments described herein provide a placeholder formation process that uses a first material having a high concentration of germanium to enhance selectivity and a second material having a lower germanium concentration to protect the placeholder during source/drain formation.

According to illustrative embodiments, a semiconductor structure includes at least one contact placeholder, where a first portion of the contact placeholder comprises SiGe having a first germanium concentration and a second portion comprises SiGe having a second germanium concentration that is lower than the first concentration. The second portion of the at least one placeholder comprises a sidewall protective liner that can prevent damage during a substrate removal process. Such embodiments provide increased control over the placeholder material replacement process, which can help prevent void formation during replacement of the placeholder material.

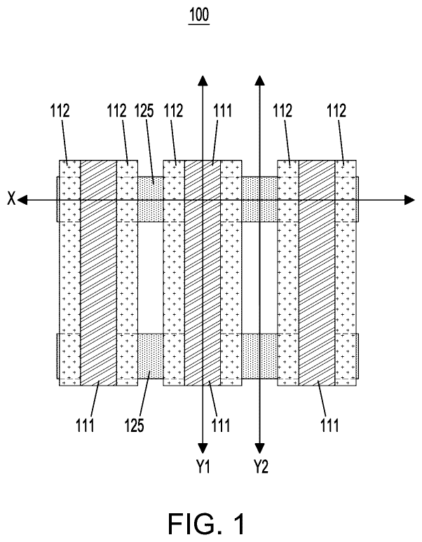

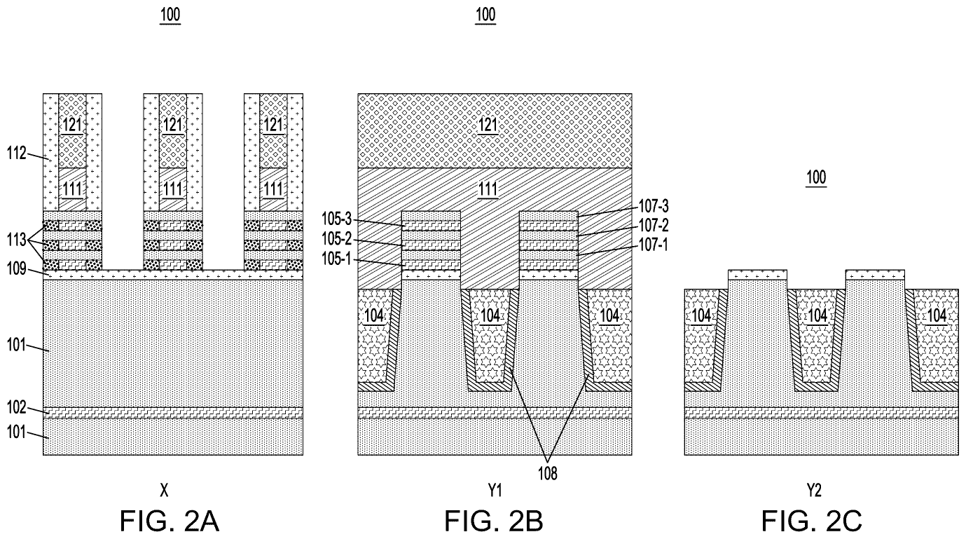

FIG. 1 illustrates a top view of a semiconductor structure 100 with lines X, Y1, and Y2 on which the cross-sectional views of FIGS. 2A-15C are based, according to an illustrative embodiment. Referring also to the cross-sectional views in FIGS. 2A, 2B, and 2C, these figures depict the semiconductor structure 100 during an intermediate fabrication step following patterning of active regions 125, formation of short trench isolation (STI) regions 104, dummy gate portions 111, gate spacers 112, bottom dielectric isolation (BDI) layer 109, stacked structures comprising sacrificial layers 105-1, 105-2, and 105-3 (collectively “sacrificial layers 105”) and channel layers 107-1, 107-2, and 107-3 (collectively “channel layers 107”), inner spacers 113, and a hardmask (HM) layer 121.

In some embodiments, the active regions 125 correspond to source/drain regions of respective transistors. In illustrative embodiments, the sacrificial layers 105 comprise SiGe and the channel layers 107 comprise silicone. In an illustrative embodiment, the sacrificial layers 105 comprise a germanium concentration of about 25% (for example, SiGe25), but the embodiments are not necessarily limited to SiGe25 for the sacrificial layers 105.

While three sacrificial layers 105 and three channel layers 107 are shown, embodiments described herein are not necessarily limited to the shown number of sacrificial layers 105 and channel layers 107, and there may be more or less layers in the same alternating configuration depending on design constraints. The sacrificial layers 105, as described further herein, are eventually removed, and replaced by gate structures.

The sacrificial layers 105 and the channel layers 107 are epitaxially grown on a semiconductor substrate 101. The terms “epitaxial growth and/or deposition” and “epitaxially formed and/or grown,” mean the growth of a semiconductor material (crystalline material) on a deposition surface of another semiconductor material (crystalline material), in which the semiconductor material being grown (crystalline over layer) has substantially the same crystalline characteristics as the semiconductor material of the deposition surface (seed material). In an epitaxial deposition process, the chemical reactants provided by the source gases are controlled, and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed.

The semiconductor substrate 101 may be formed of any suitable semiconductor structure, including various silicon-containing materials such as Si, SiGe, silicon germanium carbide (SiGeC), silicon carbide (SiC), and multi-layers thereof. Although silicon is the predominantly used semiconductor material in wafer fabrication, alternative semiconductor materials can be employed as additional layers such as, but not limited to, germanium (Ge), gallium arsenide (GaAs), gallium nitride (GaN), SiGe, cadmium telluride (CdTe), and zinc selenide (ZnSe).

As used herein, “frontside or “first side” refers to a side on top of the semiconductor substrate 101 and/or in front of, on top of, or in an upward direction from the stacked gate and channel layers of the transistors in the orientation shown in the cross-sectional figures. As used herein, “backside” or “second side” refers to a side below the semiconductor substrate 101 and/or behind, below, or in a downward direction from the stacked gate and channel layers of the transistors in the orientation shown in the cross-sectional figures (for example, opposite the “frontside”).

An etch stop layer 102 is formed in the semiconductor substrate 101. The etch stop layer 102 may comprise a buried oxide (BOX) layer or SiGe, or another suitable material such as a III-V semiconductor epitaxial layer.

The isolation regions 104 and corresponding liner portions 108 are formed between the nanosheet stacks, the BDI layer 109 and the semiconductor substrate 101. In illustrative embodiments, the isolation regions 104 comprise an oxide (e.g., SiOₓ) and the liner portions 108 comprise a nitride (e.g., SiN, SiON, SiCN, BN, SiBCN, SiOCN).

The dummy gate portions 111 are formed on the uppermost channel layers 107-3 and around the stacked nanosheet configurations of the sacrificial layers 105 and channel layers 107. The dummy gate portions 111 include but are not limited to an amorphous silicon (a-Si) layer. The dummy gate portions 111 are deposited using deposition techniques such as, for example, CVD, PECVD, RFCVD, PVD, ALD, MBD, PLD, LSMCD, sputtering and/or plating, followed by a planarization process, such as, CMP, and lithography and etching steps to remove excess dummy gate material, and pattern the deposited layer. The HM layer 121 is formed on the dummy gate portions 111. The HM layer 121 can comprise, for example, a nitride such as SiN or other nitride material.

The gate spacers 112 are formed on sides of the HM layer 121 and dummy gate portions 111 by one or more of the deposition techniques noted in connection with deposition of the dummy gate material. The spacer material can comprise for example, one or more dielectrics, such as, but not limited to, SiN, SiON, SiOC, SiCN, BN, SiBN, SiBCN, SiOCN, SiOₓ, and combinations thereof. According to an embodiment, the HM layer 121 and gate spacers 112 can be the same material or different materials. The gate spacers 112 can be formed by any suitable techniques such as deposition followed by directional etching. Deposition may include, but is not limited to, ALD or CVD. Directional etching may include but is not limited to, reactive ion etching (RIE).

Due to, for example, germanium in the sacrificial layers 105, lateral etching of the sacrificial layers 105 can be performed selective to the channel layers 107, such that the side portions of the sacrificial layers 105 can be removed to create vacant areas to be filled in by the inner spacers 113. The material of the inner spacers 113 can comprise, but is not necessarily limited to, a nitride, such as, SiN, SiON, SiCN, BN, SiBN, SiBCN or SiOCN. Like the gate spacers 112, the inner spacers 113 can be formed by any suitable techniques such as deposition followed by directional etching.

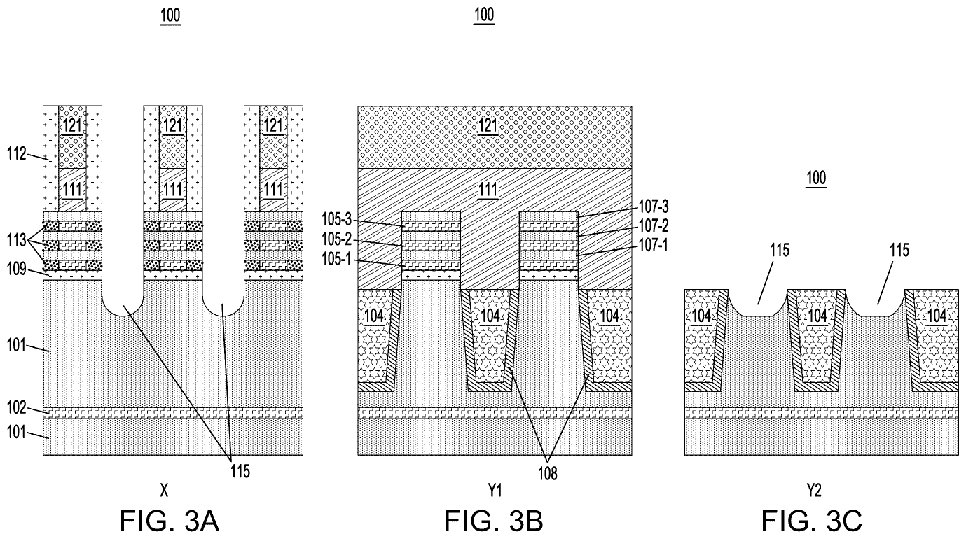

Referring to FIGS. 3A-3C, exposed portions of the BDI layer 109 between the stacked structures of the sacrificial layers 105 and the channel layers 107 are removed in a first removal process. Following removal of the exposed portions of the BDI layer 109 between the stacked structures of sacrificial layers 105 and the channel layers 107, underlying portions of the semiconductor substrate 101 are removed, such that portions of the semiconductor substrate 101 are recessed to create shallow trenches 115 in the semiconductor substrate 101. The semiconductor substrate 101 can be removed using, for example, a dry etching process using a RIE or ion beam etch (IBE) process, a wet chemical etch process or a combination of these etching processes.

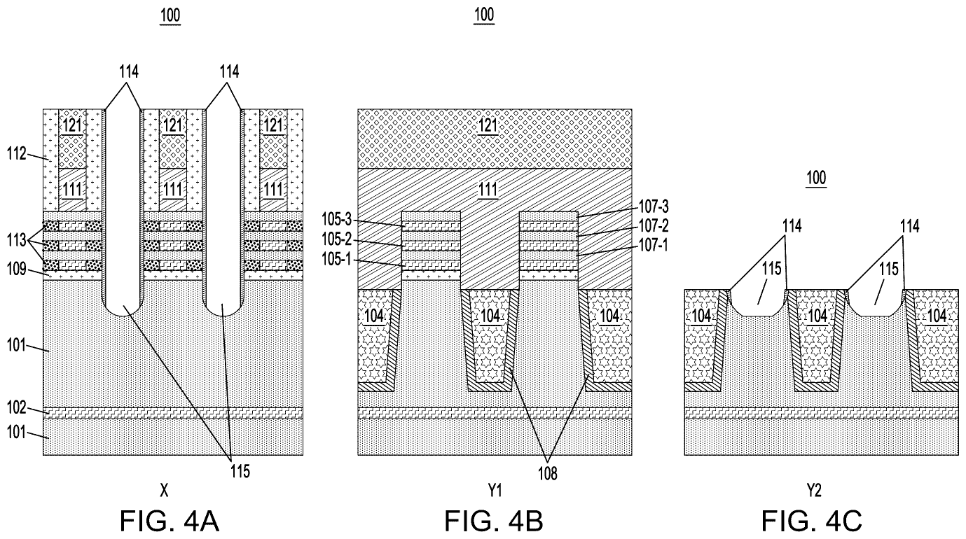

FIGS. 4A-4C show the semiconductor structure 100 following formation of a protective liner 114, according to an illustrative embodiment. The protective liner 114 is formed on vertical sidewalls of the channel layers 107, the BDI layer 109, the gate spacers 112, the inner spacers 113, and the shallow trenches 115, as shown in FIGS. 4A and 4C. In some embodiments, the protective liner 114 is formed using a conformal dielectric liner deposition process followed by an etching process, such as RIE. The protective liner 114 may be formed of SiN or another suitable material such as SiBCN, SiCOH, SINCH, etc.

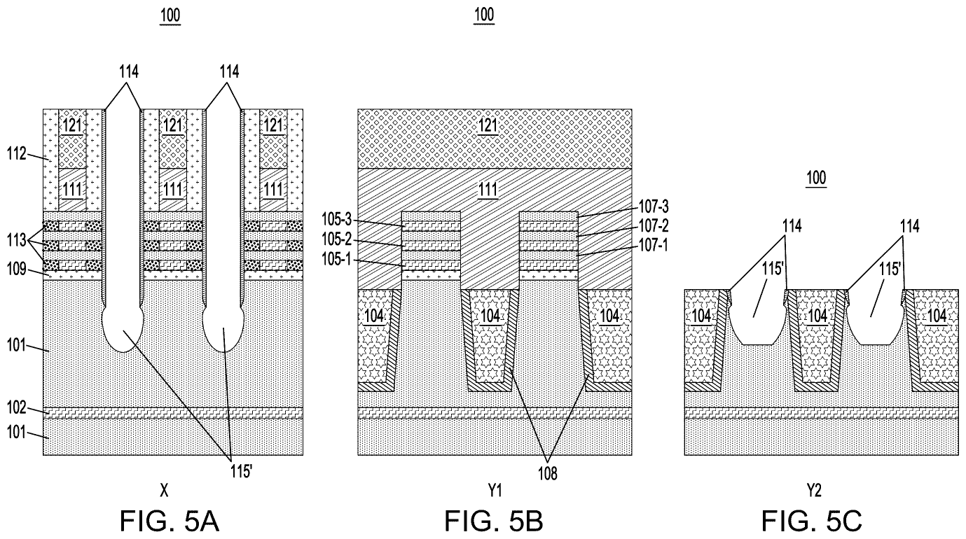

FIGS. 5A-5C show the semiconductor structure 100 following formation of a placeholder cavity with lateral enlargement, according to an illustrative embodiment. More specifically, following the formation of the protective liner 114, an etching process is performed to extend and widen the shallow trenches 115 further into the semiconductor substrate 101, thereby forming placeholder cavity trenches 115′. The placeholder cavity trenches 115′ may be formed by performing a deep etch into the semiconductor substrate 101 followed by lateral etch to widen the placeholder cavity trenches 115′.

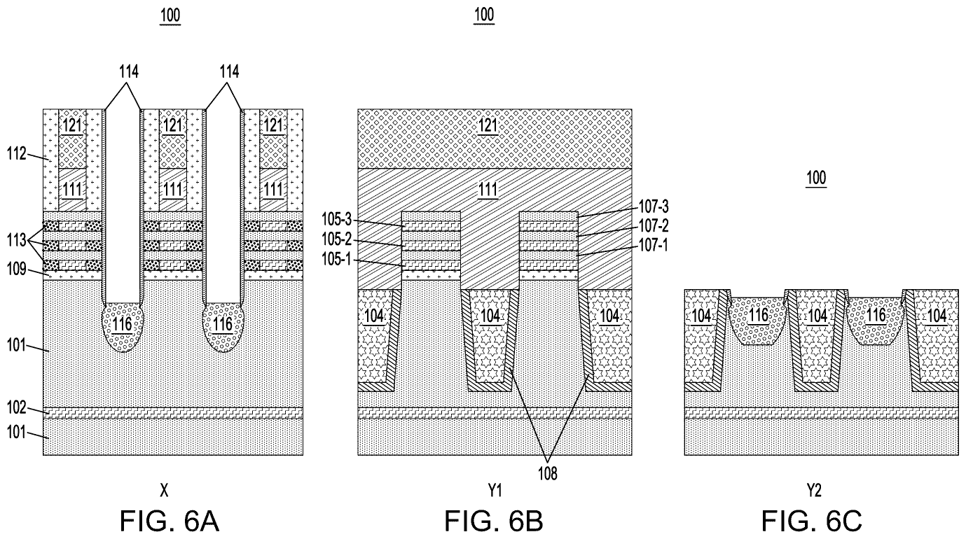

Referring to FIGS. 6A-6C, a first placeholder layer 116 is formed in the placeholder cavity trenches 115′. In illustrative embodiments, the first placeholder layer 116 can comprise, for example, SiGe having a first germanium concentration (e.g., a germanium concentration in the range of 40 to 70%). The first placeholder layer 116 can be epitaxially grown from the exposed portions of the semiconductor substrate 101 to ensure proper uniformity.

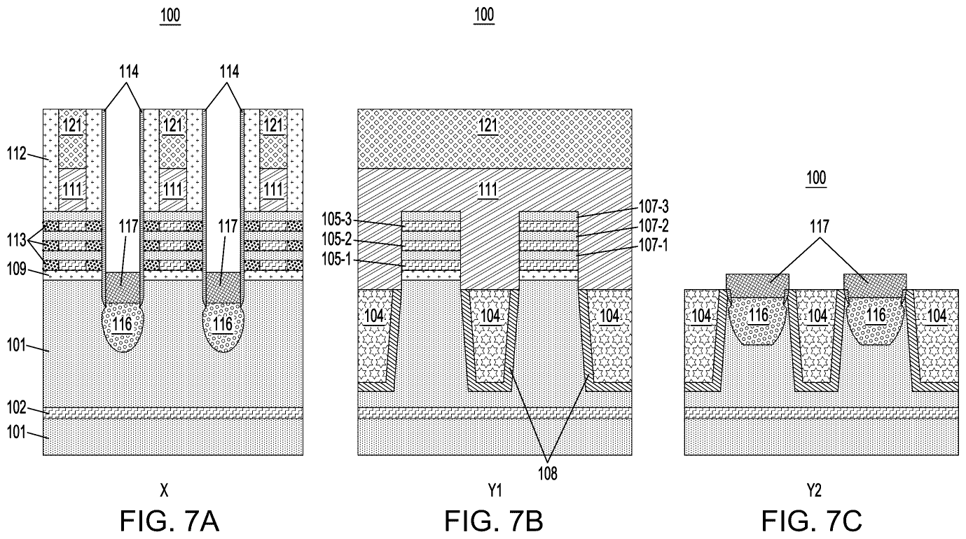

Referring to FIGS. 7A-7C, a second placeholder layer 117 is formed in the placeholder cavity trenches 115′. In illustrative embodiments, the second placeholder layer 117 can comprise, for example, SiGe having a second germanium concentration (e.g., a germanium concentration in the range of 0 to 30%). The second placeholder layer 117 can be epitaxially grown from the exposed portions of the first placeholder layer 116, for example. The second placeholder layer 117 can be formed so that a top surface of the second placeholder layer 117 is level with the top surface of the BDI layer 109. In some embodiments, the second placeholder layer 117 can have a thickness of approximately 20 nm. In some embodiments, the combined thickness of the first placeholder layer 116 and the second placeholder layer 116 can be in the range of approximately 30-60 nm of which approximately 20-45 nm corresponds to the second placeholder layer 117 and the remaining portion corresponds to the first placeholder layer 116.

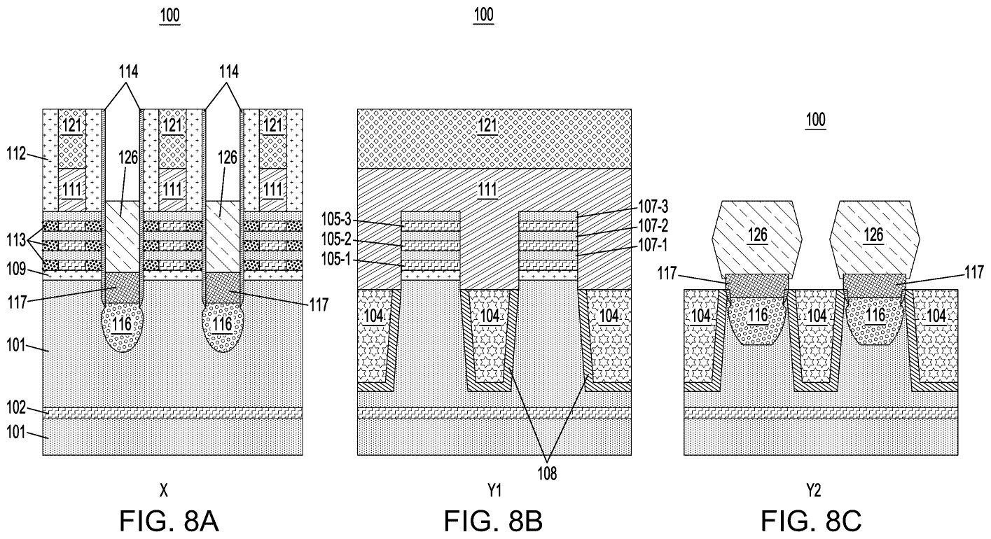

FIGS. 8A-8C show the semiconductor structure 100 following the formation of source/drain regions 126, according to an illustrative embodiment. The bottom portions of the source/drain regions 126 are positioned above the sacrificial placeholders 127 and between the stacked structure of sacrificial layers 105 and channel layers 107. Side surfaces of respective ones of the channel layers 107 contact a side surface of at least one adjacent source/drain region 126. The top surfaces of the source/drain regions 126 are above the top surfaces of uppermost ones of the channel layers 107. The source/drain regions 126 can be epitaxially grown from the exposed surfaces of the corresponding second placeholder layer 117.

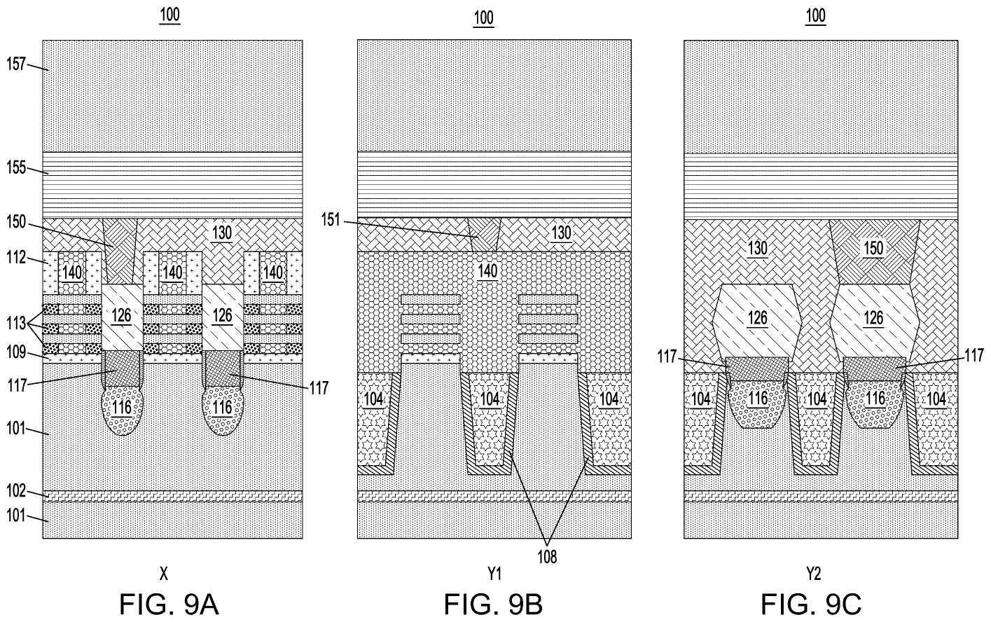

FIGS. 9A-9C show the semiconductor structure 100 following CMP, RMG formation, MOL contact formation, frontside BEOL interconnect formation, and carrier wafer bonding, according to an illustrative embodiment. Specifically, an ILD layer 130 is deposited to fill in portions on and around the source/drain regions 126. The ILD layer 130 is deposited using deposition techniques such as, for example, CVD, PECVD, RFCVD, PVD, ALD, MBD, PLD, and/or LSMCD, followed by a planarization process, such as, CMP to remove excess portions of the ILD layer 130 deposited on top of the gate HM layer 121 and gate spacers 112, and to remove the gate HM layer 121 and portions of the gate spacers 112 to expose the dummy gate portions 111. The ILD layer 130 may comprise, for example, SiOx, SiOC, SiOCN or some other dielectric.

The dummy gate portions 111 and the sacrificial layers 105 are selectively removed to create vacant areas, and gate regions 140 are formed in the vacant areas. For example, the dummy gate portions 111 can be selectively removed using hot ammonia to remove a-Si, and the sacrificial layers 105 can be selectively removed with respect to the channel layers 107 using, for example, a dry HCl etch.

Following removal of the dummy gate portions 111 and the sacrificial layers 105, the channel layers 107 are suspended, and the gate regions 140, including gate and dielectric portions are formed in the vacant areas left by removal of the dummy gate portions 111 and the sacrificial layers 105. In illustrative embodiments, each gate region 140 includes a gate dielectric layer such as, for example, a high-K dielectric layer such as, but not limited to, HfO₂ (hafnium oxide), ZrO₂ (zirconium dioxide), hafnium zirconium oxide, Al₂O₃ (aluminum oxide), and Ta₂O₅ (tantalum oxide). Examples of high-k materials also include, but are not limited to, metal oxides such as hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate.

According to an embodiment, the gate regions 140 each include a metal gate portion including a work-function metal (WFM) layer, including but not necessarily limited to, for a pFET, titanium nitride (TiN), tantalum nitride (TaN) or ruthenium (Ru), and for an nFET, TiN, titanium aluminum nitride (TiAlN), titanium aluminum carbon nitride (TiAlCN), titanium aluminum carbide (TiAlC), tantalum aluminum carbide (TaAlC), tantalum aluminum carbon nitride (TaAlCN) or lanthanum (La) doped TiN, TaN, which can be deposited on the gate dielectric layer. The metal gate portions can also each further include a gate metal layer such as, but not limited to, metals such as, for example, tungsten, cobalt, zirconium, tantalum, titanium, aluminum, ruthenium, copper, metal carbides, metal nitrides, transition metal aluminides, tantalum carbide, titanium carbide, tantalum magnesium carbide, or combinations thereof deposited on the WFM layer and the gate dielectric layer. It should be appreciated that various other materials may be used for the metal gate portions as desired.

Additional ILD material is deposited on the ILD layer 130, and frontside source/drain contacts 150 are formed in the ILD layer 130 to contact respective top surfaces of the source/drain regions 126. To form the frontside source/drain contacts 150, openings are created through portions of the ILD layer 130, exposing portions of the source/drain regions 126 on which the frontside source/drain contacts 150 are to be formed. According to an embodiment, masks are formed on parts of the ILD layer 130, and exposed portions of the ILD layer 130 corresponding to where the openings are to be formed are removed using, for example, a dry etching process using a RIE or ion beam etch (IBE) process, a wet chemical etch process or a combination of these etching processes. A dry etch may be performed using a plasma. Such wet or dry etch processes include, for example, IBE by Ar/CHF3 based chemistry.

Metal layers can then be deposited in the openings to form the frontside source/drain contacts 150. The metal layers may include a silicide layer, such as Ni, Ti, NiPt, etc., a metal adhesion layer, such as TiN, and a conductive metal fill layer, such as W, Al, Co, Ru, etc., and can be deposited using, for example, a deposition technique such as CVD, PECVD, RFCVD, PVD, ALD, MBD, PLD, LSMCD, sputtering and/or plating, followed by planarization processes such as CMP to remove excess portions of the metal layers from on top of the ILD layer 130.

At least one frontside gate contact 151 is formed through the ILD layer 130 to land on and contact a corresponding gate region 140. The process and materials used for forming the frontside gate contact 151 are similar to those used for forming the frontside source/drain contacts 150.

The frontside BEOL interconnects 155 are formed on the ILD layer 130 and include various BEOL interconnect structures. The carrier wafer 157 may be formed of materials similar to those used in the semiconductor substrate 101 and can be formed over the frontside BEOL interconnects 155 using a wafer bonding process, such as dielectric-to-dielectric bonding.

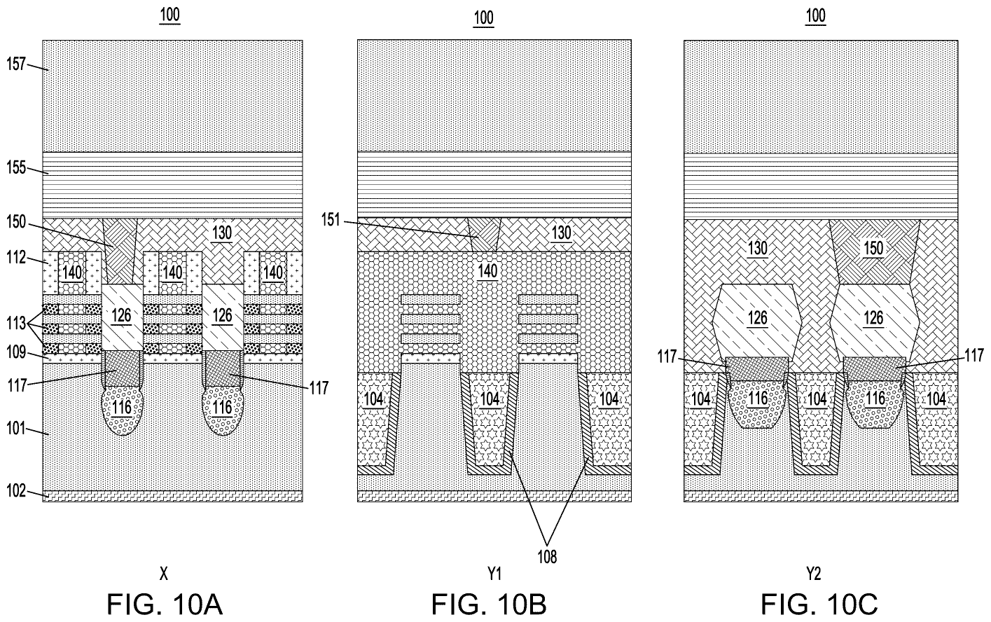

Referring to FIGS. 10A-10C, using the carrier wafer 157, the semiconductor structure 100 may be “flipped” (for example, rotated 180 degrees) so that the structure is inverted. In addition, the semiconductor substrate 101 is removed from the backside of the semiconductor structure 100 stopping at the etch stop layer 102. For example, the semiconductor substrate 101 can be selectively etched with an etchant that selectively etches silicon with respect to a material of the etch stop layer 102.

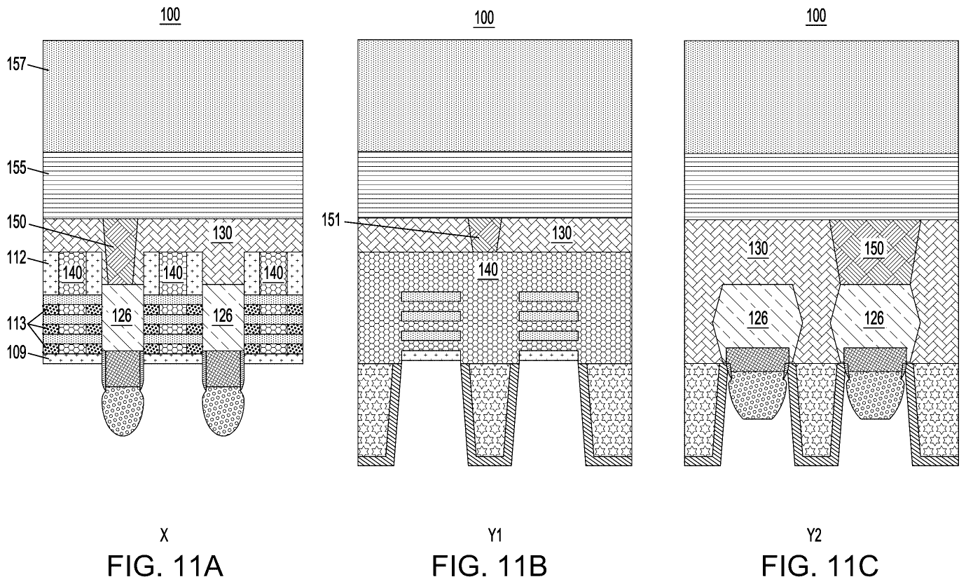

Referring to FIGS. 11A-11C, the etch stop layer 102 and the remaining semiconductor substrate 101 are removed. The etching processes for removal of the etch stop layer 102 include but are not limited to IBE using Ar/CHF3 based chemistry. Etchants for removing the semiconductor substrate 101 include, for example, potassium hydroxide (KOH) and TMAH.

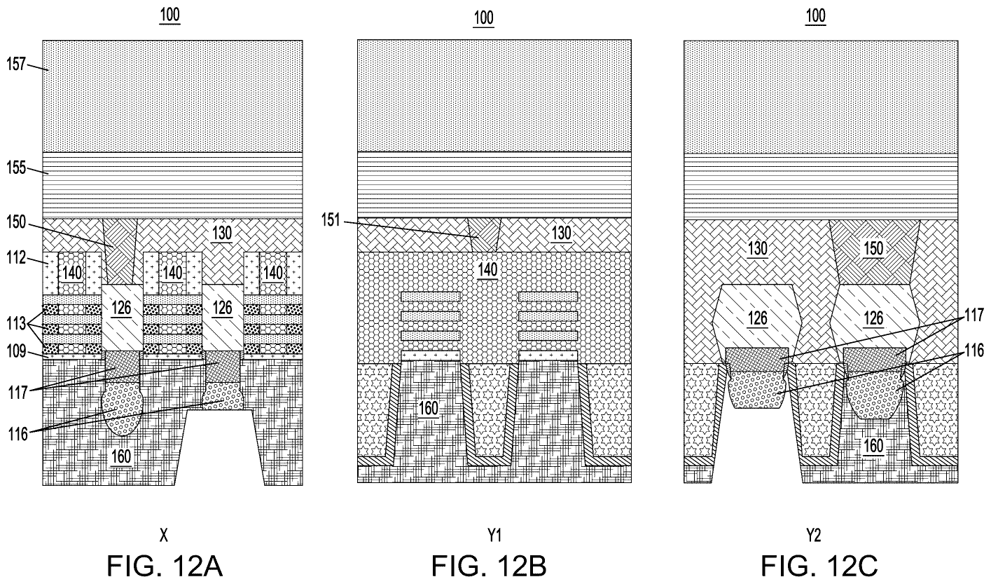

FIGS. 12A-12C show cross-sectional views of the semiconductor structure 100, respectively corresponding to lines X, Y1, and Y2, following formation of a backside ILD layer 160 and backside contact patterning, according to an illustrative embodiment. The backside ILD layer 160 can be deposited using deposition techniques such as CVD, PECVD, RFCVD, PVD, ALD, MBD, PLD, and/or LSMCD, followed by a planarization process such as CMP to cause the backside ILD layer 160. The backside ILD layer 160 may comprise, for example, SiOₓ, SiOC, SiOCN or some other dielectric.

The backside contact patterning can include depositing a mask with openings where backside source/drain contacts are to be formed, and then selectively removing the exposed portions of the backside ILD layer 160 using a dry etching process such as RIE or IBE, a wet chemical etching process, or a combination of these etching processes. A dry etch may be performed using a plasma. Such wet or dry etch processes include, for example, IBE using Ar/CHF3 based chemistry. The exposed portions of the backside ILD layer 160 can be removed to expose bottom portions of the first placeholder layer 116.

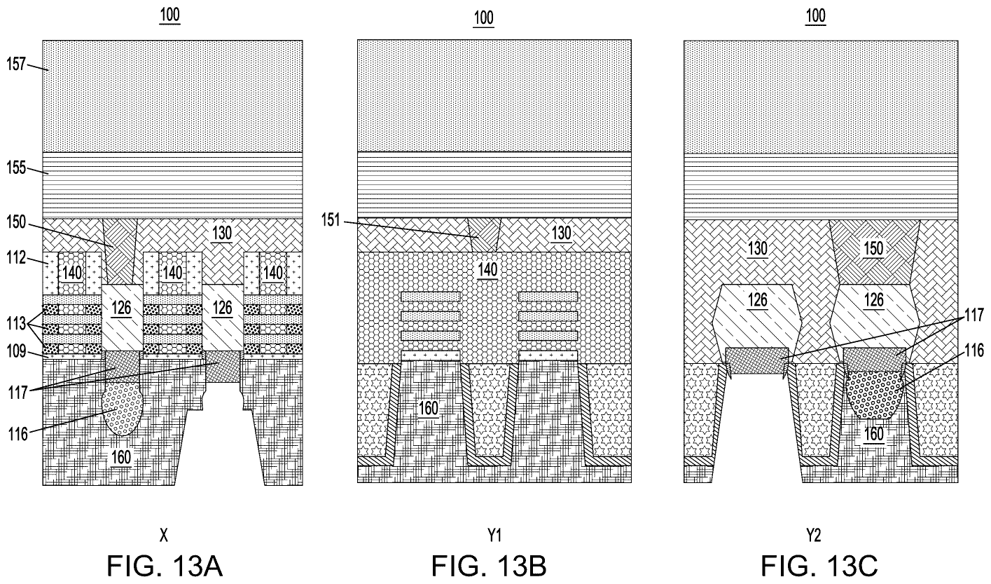

FIGS. 13A-13C show cross-sectional views of the semiconductor structure 100, respectively corresponding to lines X, Y1, and Y2, following selective removal of portions of the first placeholder layer 116, according to an illustrative embodiment. The portion of the first placeholder layer 116 that is exposed can be selectively removed, thereby exposing a backside portion of the second placeholder layer 117. The first placeholder layer 116 can be selectively removed using, for example, a selective dry or wet etch process.

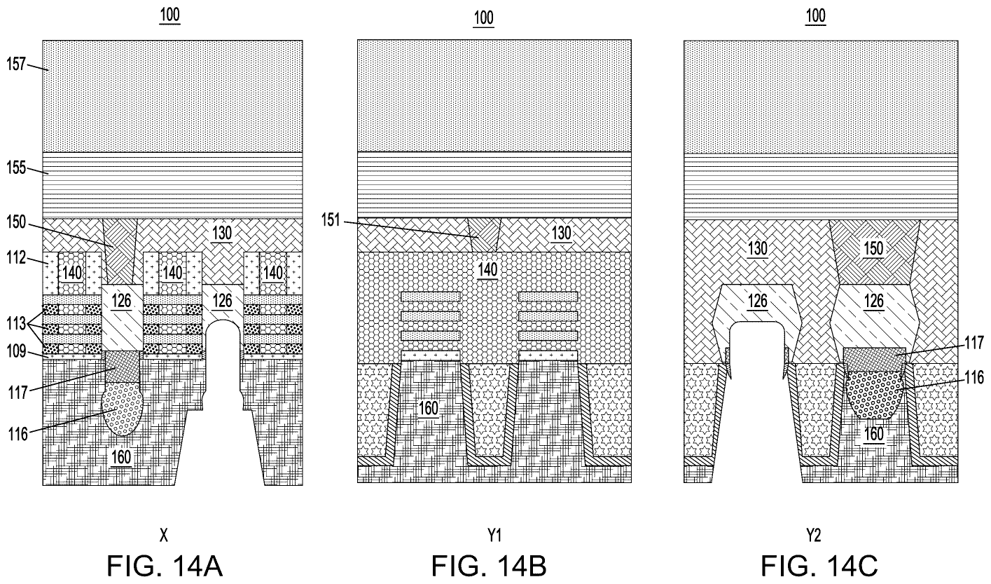

FIGS. 14A-14C show cross-sectional views of the semiconductor structure 100, respectively corresponding to lines X, Y1, and Y2, following selective removal of a portion of the second placeholder layer 117, according to an illustrative embodiment. The portion of the second placeholder layer 117 that is exposed can be removed to expose a backside portion of the corresponding source/drain region 126. The first placeholder layer 116 can be selectively removed using, for example, a directional etch.

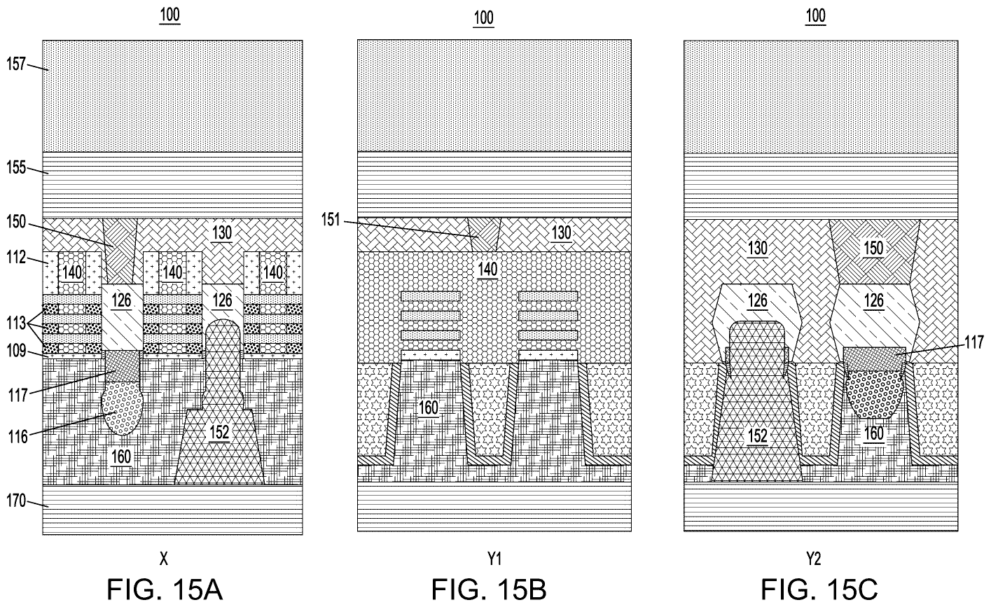

FIGS. 15A-15C show cross-sectional views of the semiconductor structure 100, respectively corresponding to lines X, Y1, and Y2, following backside contact and backside interconnect formation, according to an illustrative embodiment. Backside source/drain contacts 152 are formed by fill and planarization of contact material. The contact material of the backside source/drain contacts 152 may be similar to that of the frontside source/drain contacts 150, for example. The backside source/drain contacts 152 contact respective backsides of the source/drain regions 126. Backside BEOL layers 170 (also referred to herein as backside interconnects) are formed on the backside ILD layer 160 and on the backside source/drain contacts 153. The backside BEOL layers 170 can include various backside power delivery network structures such as, but not limited to, interconnects in a power supply path from voltage regulator modules (VRMs) to circuits. The interconnects can comprise, for example, power and ground planes in circuit boards, cables, connectors, and capacitors associated with a power supply. Backside power delivery prevents BEOL routing congestion, resulting in power performance benefits. The backside source/drain contacts 152 are connected to the backside BEOL layers 170. In some embodiments, the backside BEOL layers 170 can alternatively or additionally be used for routing of signals, including power and/or clock signals as non-limiting examples.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETS, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

In one embodiment, a semiconductor device includes a first source/drain contact disposed beneath a first source/drain region and a placeholder disposed beneath a second source/drain region. The placeholder includes a first portion comprising a first material having a first concentration of germanium and a second portion comprising a second material having a second concentration of germanium that is different than the first concentration.

In embodiments, the second concentration of the second material may be lower than the first concentration of the first material, and the first portion of the placeholder may be disposed below the second portion of the placeholder.

In embodiments, the first portion of the placeholder may be disposed between the second portion of the placeholder and the second source/drain region.

In embodiments, the first source/drain contact may be a backside source/drain contact; and the second source/drain region may be connected to a frontside source/drain contact.

In embodiments, the first portion of the placeholder may include a cross-sectional profile having vertical sides.

In embodiments, the semiconductor device may include a protective liner disposed on vertical sidewalls of the first portion of the placeholder.

In embodiments, the second portion of the placeholder may include a cross-sectional profile with curved sides.

In embodiments, the first source/drain contact may extend into the first source/drain region.

In embodiments, the first concentration of germanium may be between 40% and 70%, and the second concentration of germanium may be between 0% and 30%.

In another embodiment, a semiconductor device includes a first source/drain region, a second source/drain region, a backside contact disposed beneath the first source/drain region, and a placeholder disposed beneath the second source/drain region. The placeholder includes a high germanium content portion and a low germanium content portion, where the high germanium content portion is adjacent to the second source/drain region.

In embodiments, the first source/drain region is not connected to a frontside contact.

In embodiments, the high germanium content portion may be disposed between the second source/drain region and the low germanium content portion.

In embodiments, the semiconductor device may include a protective liner disposed on at least a portion of the low germanium content portion of the placeholder.

In embodiments, the low germanium content portion of the placeholder may include a cross-sectional profile having vertical sides.

In embodiments, the high germanium content portion of the placeholder may include a ball-shaped cross-sectional profile.

In yet another embodiment, a method includes performing a first etch process to create a trench in a semiconductor substrate, forming a protective liner on vertical sidewalls of the trench, and performing a second etch process to deepen the trench below the protective liner and to laterally enlarge the portion of the trench that is below the protective liner. The method includes forming a first portion of a placeholder in the trench, where the first portion includes a first material having a first concentration of germanium. The method also includes forming a second portion of the placeholder adjacent to the first portion, where the second portion comprises a second material having a second concentration of germanium that is different than the first concentration.

In embodiments, the method includes forming a source/drain region on a top surface of the second portion of the placeholder.

In embodiments, the method includes forming a backside contact connecting the source/drain region to a back-end-of-line interconnect layer.

In embodiments, forming the backside contact may include removing at least the first portion of the placeholder selective to at least the second portion of the placeholder, performing a directional etch to remove at least the second portion of the placeholder, and forming the backside contact in a space corresponding to at least the removed first portion and the second portion of the placeholder.

The above-described embodiments advantageously utilize two or more materials with different germanium concentrations to form one or more contact placeholders. Such embodiments can help prevent damage to the placeholder when selectively removing silicon substrate. For example, a higher germanium concentration placeholder material can provide improved selectivity for substrate removal, and a lower germanium concentration placeholder material can help protect the placeholder during removal of the silicon substrate.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times, and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a first source/drain contact disposed beneath a first source/drain region; and
a placeholder disposed beneath a second source/drain region, wherein the placeholder comprises a first portion comprising a first material having a first concentration of germanium and a second portion comprising a second material having a second concentration of germanium that is different than the first concentration.

2. The semiconductor device of claim 1, wherein the second concentration of the second material is lower than the first concentration of the first material, and wherein the first portion of the placeholder is disposed below the second portion of the placeholder.

3. The semiconductor device of claim 1, wherein the first portion of the placeholder is disposed between the second portion of the placeholder and the second source/drain region.

4. The semiconductor device of claim 1, wherein:
the first source/drain contact is a backside source/drain contact; and
the second source/drain region is connected to a frontside source/drain contact.

5. The semiconductor device of claim 1, wherein the first portion of the placeholder comprises a cross-sectional profile having vertical sides.

6. The semiconductor device of claim 1, further comprising:
a protective liner disposed on vertical sidewalls of the first portion of the placeholder.

7. The semiconductor device of claim 1, wherein the second portion of the placeholder comprises a cross-sectional profile with curved sides.

8. The semiconductor device of claim 1, wherein:
the first source/drain contact extends into the first source/drain region.

9. The semiconductor device of claim 1, wherein the first concentration of germanium is between 40% and 70%.

10. The semiconductor device of claim 1, wherein the second concentration of germanium is between 0% and 30%.

11. A semiconductor device comprising:
a first source/drain region;
a second source/drain region;
a backside contact disposed beneath the first source/drain region; and
a placeholder disposed beneath the second source/drain region, wherein the placeholder comprises a high germanium content portion and a low germanium content portion, and wherein the high germanium content portion is adjacent to the second source/drain region.

12. The semiconductor device of claim 11, wherein the first source/drain region is not connected to a frontside contact.

13. The semiconductor device of claim 11, wherein the high germanium content portion is disposed between the second source/drain region and the low germanium content portion.

14. The semiconductor device of claim 11, further comprising:
a protective liner disposed on at least a portion of the low germanium content portion of the placeholder.

15. The semiconductor device of claim 11, wherein the low germanium content portion of the placeholder comprises a cross-sectional profile having vertical sides.

16. The semiconductor device of claim 11, wherein the high germanium content portion of the placeholder comprises a ball-shaped cross-sectional profile.

17. A method comprising:
performing a first etch process to create a trench in a semiconductor substrate;
forming a protective liner on vertical sidewalls of the trench;
performing a second etch process to deepen the trench below the protective liner and to laterally enlarge a portion of the trench that is below the protective liner;
forming a first portion of a placeholder in the trench, wherein the first portion comprises a first material having a first concentration of germanium; and
forming a second portion of the placeholder adjacent to the first portion, wherein the second portion comprises a second material having a second concentration of germanium that is different than the first concentration.

18. The method of claim 17, further comprising:
forming a source/drain region on a top surface of the second portion of the placeholder.

19. The method of claim 18, further comprising:
forming a backside contact connecting the source/drain region to a back-end-of-line interconnect layer.

20. The method of claim 19, wherein forming the backside contact comprises:
removing at least the first portion of the placeholder selective to at least the second portion of the placeholder;
performing a directional etch to remove at least the second portion of the placeholder; and
forming the backside contact in a space corresponding to at least the removed first portion and the second portion of the placeholder.
